(19) United States
(12) Patent Application Publication
(10) Pub. No.: US 2013/0302578 A1
(43) Pub. Date: Nov. 14, 2013

(54) COATING PARTICLES

(71) Applicants: Michael Delpier, Houston, TX (US); Dustin L. Hoffman, Cypress, TX (US); Peter M. On, Houston, TX (US)

(72) Inventors: Michael Delpier, Houston, TX (US); Dustin L. Hoffman, Cypress, TX (US); Peter M. On, Houston, TX (US)

(21) Appl. No.: 13/981,078

(22) PCT Filed: Feb. 28, 2011
(86) PCT No.: PCT/US2011/026492

§ 371 Date: Jul. 22, 2013

(51) Int. Cl. H05K 5/03; B05D 1/20

(52) U.S. Cl. CPC H05K 5/03; B05D 1/20
USPC 428/206; 427/598

(57) ABSTRACT

Embodiments provide methods and apparatuses related to the deposition of coating particles. In general, mating particles my be electrically deposited on a conductive substrate. The coating particles may arranged or have their deposition altered based on a magnetic field.

### BACKGROUND

Electrocoating (e-coating) may be utilized for various purposes including protecting components and aesthetically enhancing components. For example, e-coating may protect a component from corrosion and acids by applying a substantially even an top layer on the component. Alternatively, e-coating may visually enhance a component by applying a substantially even paint layer on the component. In general, e-coating systems deposit polymers onto surfaces using a voltage differential between the component and the polymers within a bath.

### BRIEF DESCRIPTION OF THE DRAWINGS

FIG. 1 illustrates a top elevation view of an apparatus accordance with an embodiment;

FIG. 2 illustrates a cross sectional view of e apparatus of FIG. 1 in accordance with an embodiment;

FIG. 3 illustrates an apparatus in accordance with an embodiment;

FIG. 4 illustrates a top elevational view of are apparatus in accordance with an embodiment;

FIG. 5 illustrates a cross sectional view of the apparatus of FIG. 4 in accordance with an embodiment;

FIG. 6 illustrates an apparatus in accordance with an embodiment;

FIG. 7 illustrates a system in accordance with an embodiment;

FIG. 8 illustrates a system in accordance with an embodiment; and

FIGS. 9-11 illustrate flow charts in accordance with various embodiments.

### DETAILED DESCRIPTION

Electro-coating (e-coating) is a process that provides carefully controlled application of a coating, for example a transparent coat, to a metal surface. Layer thickness is controlled by providing an electrical charge to a metal substrate and immersing the metal substrate in a bath that includes coating particles, such as having a known insulation ability. As the electro-coat builds, so does the electrical insulation to the point where no more coating material can be accepted by the substrate. This process may provide a coat to a known thickness by regulating the electrical charge on the component or substrate.

In the present disclosure, methods, systems, and apparatuses for controlling and varying the thickness of the coating particles across a surface of a component while utilizing an e-coating process are disclosed. Controlling the thickness of the coating particles across the surface of the component enables the integration of patterns onto the surface. In various embodiments, the coating may be a non-metallic transparent coating having a controlled pattern and thickness. The transparent coating may display various properties or characteristics of the underlying substrate in one area and conceal or suppress the various properties or characteristics in another area. While the coating may be transparent, it may conceal or suppress various properties or characteristics of the substrate because the coating may have a different hue with respect to the other thickness.

Referring to FIG. 1, an apparatus is illustrated in accordance with an embodiment of the present disclosure. The apparatus includes a conductive substrate 100 and electrically deposited coating particles 106. In various embodiments, the electrically deposited coating particles 106 disposed on the conductive substrate 100 may be arranged in a pattern 108 generated via a magnetic field.

The conductive substrate 100 can be any suitable material such as conductive metals, dielectric materials, or any material capable of holding a charge or electric potential. The conductive substrate 100 may be a material configured for use in computing systems such as, but not limited to, notebook computers, netbook computers, tablet computers, desktop computers, cell phones, smart phones, and personal digital assistants (PDAs). Additionally, the conductive substrate 100 may be utilized in other manners distinct from computing systems, such as appliances and ornamental structures. The conductive substrate 100, while illustrated as being substantially flat, is not so limited, it is expressly contemplated that the conductive substrate may comprise various shapes, curves, and undulating surfaces.

The coating particles 106 may be any coating particle configured to adhere to the conductive substrate 100 via an e-coating process. In various embodiments, the coating particles 106 may comprise metallic or non-metallic particles that are either transparent or non-transparent. The coating particles 106 may be disposed in a pattern based on magnetic fields present at the time of deposition. In the embodiment of a non-metallic transparent coating, a pattern may be displayed by altering a thickness of the non-metallic transparent coating. Where the non-metallic transparent coating is thicker, it will have a darker hue relative to where the non-metallic transparent coating is thinner. In this manner, the coating particles 106 may display a pattern.

The coating particles 106 may be arranged, and eventually cured, in a pattern. A pattern may be any shape, alphabetic character, numeral, or outline. The pattern may repeat, or alternatively include a single shape disposed in one area on the substrate or part. Additionally, a pattern may include more than one shape and may or may not repeat in a symmetric manner. In one embodiment, the pattern may be a transition of the coating particles 106 from a thick layer to a thin layer relative to one another,

Still referring to FIG. 1, the conductive substrate 100 is illustrated with electrically deposited coating particles 106 that are arranged in a pattern 108 generated via a magnetic field. As illustrated, the pattern 108 is substantially circular. The pattern 108 is comprised of a first thickness of coating particles 102 and a second thickness of the coating particles 104. In the illustrated embodiment, the first thickness 102 is less than the second thickness 104 and is configured to reveal a characteristic of the underlying conductive substrate 110. The second thickness 104 is configured to display a darker hue than the first thickness, and consequently, suppress or conceal more of the characteristics of the conductive substrate 100 relative to the first thickness 102.

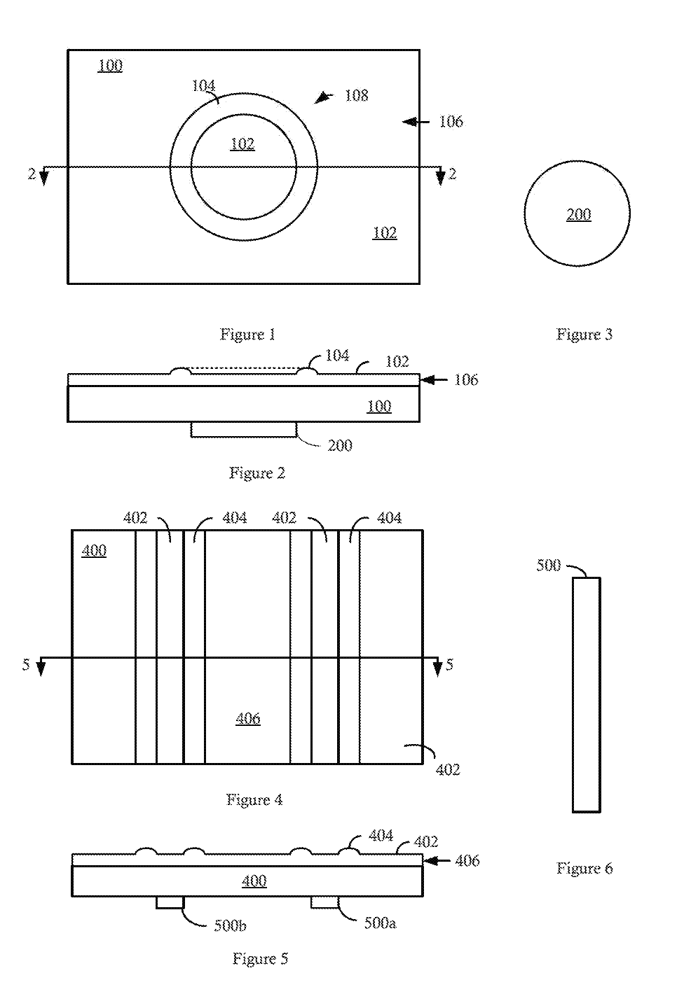

Referring, to FIG. 2, a cross sectional view of the apparatus of FIG. 1 is illustrated. As viewed in cross section, the varying thicknesses 102, 104 of the coating particles 106 are illustrated. In the illustrated embodiment, a magnet 200 is disposed on one side of the conductive substrate 100. The magnet 200 may be a magnet cut from a magnetic sheet or any other type of magnet. The magnet 200 may be adhered to the conductive substrate 100 with an adhesive, mechanical fasteners, or alternatively through its magnetic properties.

With the magnet 200 coupled to the conductive substrate 100, it may be immersed in a bath with the coating particles 106. A charge may be placed on the conductive substrate 100 to attract the coating particles 106 to the conductive substrate 100. Due to the magnetic field of the magnet 100, the deposition of the coating particles 106 may be altered. As illustrated, the coating particles 106 will be attracted to the edges of the magnet 200, thereby increasing the thickness across the surface of the conductive substrate 100 and generating the second thickness 104.

In various embodiments, the thicknesses may vary based on factors that include the amount of charge on the conductive substrate 100 and the strength of the magnet 200. In other embodiments, coating thickness can be controlled dependent upon immersion time, bath temperature, process voltage, and bath chemistry. As an example, a substrate may be immersed for 90 to 360 seconds at a bath temperature between 60 to 80 degrees Fahrenheit. The process voltage may range from 15 Volts to 500 Volts. Other times, temperatures, voltages, and/or currents are contemplated.

FIG. 3 illustrates a magnet 200 utilized to generate the magnetic field which alters the deposition of the coating particles 106 on the conductive substrate 100. While illustrated as a circle, other shapes and configurations are contemplated. Additionally, other manners of generating magnetic fields may be utilized to alter the deposition of the coating particles 106. For example, a magnetic field may be generated by passing a current or moving a charge through a wire, such as a solenoid. Based on the magnetic field, the distribution of the mating particles 106 on the conductive substrate 100 may be altered into a pattern.

Referring to FIGS. 4-6, another embodiment of an apparatus having a conductive substrate 400 and electrically deposited coating particles 406 that are arranged in a pattern generated by a magnetic field is illustrated. The conductive substrate 400 and the coating particles 406 may be similar to those of FIGS. 1-3.

FIG. 6 illustrates another embodiment of a magnet 500 utilized to generate a magnetic field to alter the deposition of the coating particles 406. In FIG. 6, the magnet 500 is a bar or length of magnetic material configured to extend across a surface of the conductive substrate 400. Similar to the distribution of coating particles 106 discussed with reference to FIGS. 1-3, the coating particles 406 may be attracted to the edges of the magnets 600a, 500b due to their magnetic fields. In this manner, a pattern may be generated on the surface of the conductive substrate 400. For example, a first thickness 402 may enable display of various characteristics of the underlying conductive substrate 400, such as metal striations. The second thickness 404 may be thicker than the first thickness and conceal or suppress more of the underlying characteristics of the conductive substrate 400, relative to the first thickness.

While FIGS. 2 and 5 illustrate the various thicknesses across the surfaces of the conductive substrates 400, 100, it should be noted that the difference in thicknesses may be on the order of one to three millimeters. Therefore, when cured, there is a negligible difference in height, yet a pattern may be visible. Other ranges of thickness are contemplated, and in various embodiments, a larger differential may be utilized to, for example, generate a textured surface.

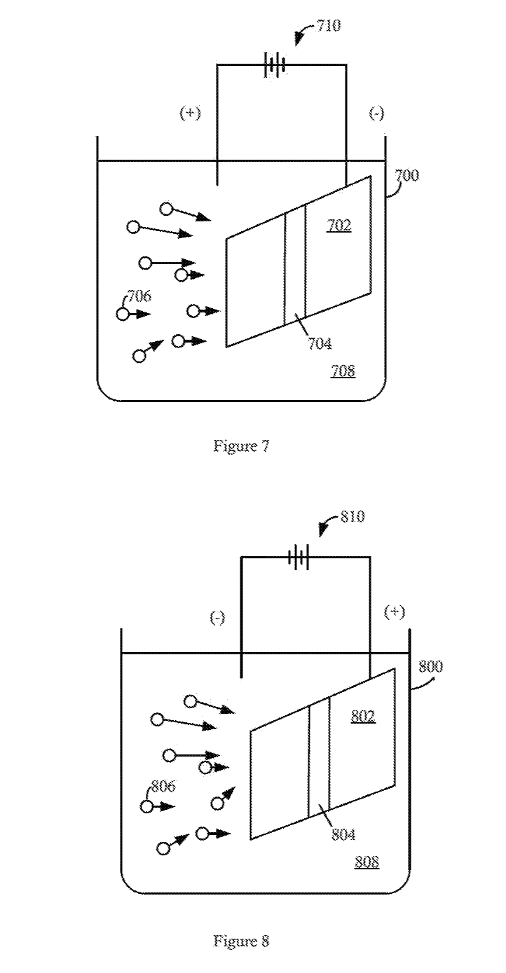

Referring to FIGS. 7 and 8, embodiments of an electrodepositing system are illustrated in accordance with the present disclosure. In the Figures, the conductive substrates 702 and 80$ have a magnet 704, 804 attached to one side. The conductive substrates 702 and $02 are immersed in a bath 708 and 808 including coating particles 706 and 806, immersing the conductive substrates may include submerging the conductive substrates, or only partially suspending the conductive substrates within the bath. In other words, the electrodepositing system of FIGS. 7 and 8 is used to e coat at least a portion of the conductive substrate 702, 802.

In the illustrated embodiments, a fluid bath 708, 808 is provided in a container 700, 800. The fluid bath may be a liquid bath that includes the coating particles 706, 806. For example, the bath may include 80-90% deionized water and 10-20% coating particles. Other combinations are contemplated, and the ratio of coating particles to liquid within the bath may be varied dependent upon various factors including the amount of coating particles to be disposed on the surface of the conductive substrates. Alternatively, the fluid bath may be a gaseous bath that includes the coating particles dispersed in gaseous form. For example, the fluid bath may be a gas in a chemical vapor disposition, plasma-enhanced chemical vapor disposition, or other type of vapor disposition.

Referring to FIG. 7, a voltage differential is applied between the fluid bath 708 and the conductive substrate 702. In FIG. 7, a negative charge is applied to the conductive substrate 702. A positive charge is applied to the fluid bath 708 and coating particles 706 causing the coating particles 706 to adhere to the surfaces of the conductive substrate 702. Alternatively, FIG. 8 illustrates the conductive substrate 802 having a positive charge and a negative charge being applied to the fluid bath 808. The electric potential generated between the positive and negative charges, once again, may cause the coating particles 806 to adhere to the surface of the conductive substrate 802. The deposition of the coating particles 806, however, may be altered by the magnetic field generated by magnets 704, 804.

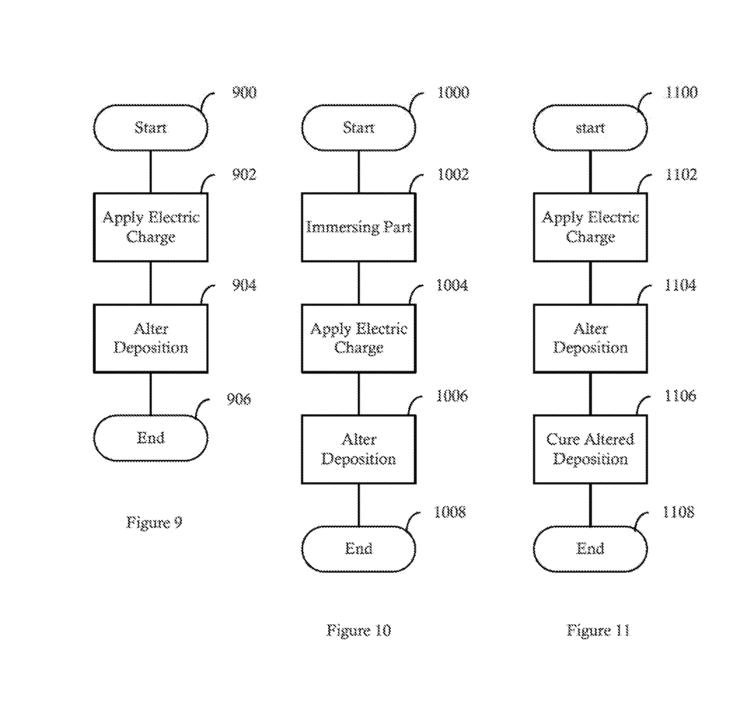

FIGS. 9-11 illustrate flow diagrams associated with various embodiments of the present disclosure. The flow diagrams illustrate methods that may be associated with the systems of FIG. 7 or 8, and the apparatuses of FIGS. 1-6. While illustrated in a particular order, the disclosure is not so limited.

Referring to FIG. 9, the method may begin at 900 and progress to 902 where an electric charge is applied to a conductive substrate immersed in a bath that includes coating particles. The electric charge ma be a positive charge or a negative charge and is configured to uniformly distribute the coating particles on the conductive substrate. Progressing to block 904, the system may utilize a magnetic field to alter the deposition of the coating particles on the conductive substrate. In one embodiment, a magnet may be attached to one side of the conductive substrate. In another embodiment, a magnetic field may be generated utilizing other devices such as a solenoid. Based on the magnetic field, the coating particles may form into a pattern on the surface of the conductive substrate, and the method may end at 906.

Referring to FIG. 10, another method is illustrated. The method may begin at 1000 and progress to 1002 where the conductive substrate is immersed in the bath containing the coating particles. In one example, the conductive substrate may be only partially immersed in the bath. In another example, the conductive substrate may be completely submerged into the bath. Immersion, either wholly or partially, may also provide a manner of generating a pattern.

With the conductive substrate immersed in the bath, the method may continue to 1004 where an electric charge is applied to the conductive substrate. The charge applied to the conductive substrate may be either a positive charge or a negative charge. The electric charge is configured to uniformly distribute the coating particles on the conductive substrate. Progressing to 1016, the system may utilize a magnetic field to alter the deposition of the coating particles on the conductive substrate. In one embodiment, a magnet may be attached to one side of the conductive substrate. In another embodiment, a magnetic field may be generated utilizing other devices such as a solenoid. Based on the magnetic field, the coating particles may form into a pattern on the surface of the conductive substrate, and the method may end at 1005.

Referring to FIG. 11, another method is illustrated. The method begins at 100 and progress to 1102, where an electric charge is applied to a conductive substrate immersed in a bath that includes coating particles. The electric charge may be a positive char or a negative charge and is configured to uniformly distribute the coating particles on the conductive substrate. Progressing to block 1104, the system may utilize a magnetic field to alter the deposition of the mating particles on the conductive substrate. In one embodiment, a magnet may be attached to one side of the conductive substrate. In another embodiment, a magnetic field may be generated utilizing other devices such as a solenoid. Based on the magnetic field, the coating particles may form into a pattern on the surface of the conductive substrate.

After the deposition of the coating particles on the conductive substrate or conductive substrate, the method may progress to 1106 where the coating is cured. Curing may comprise heating the metal substrate, applying ultraviolet light, or allowing to the coating particles to dry on removed from the bath. After curing, the method may end at 1108.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope of this disclosure. Those with skill in the art will readily appreciate that embodiments may be implemented in a wide variety of ways. This application is intended to cover any adaptations or variations of the embodiments discussed herein. Therefore, it is manifestly intended that embodiments be limited only by the claims and the equivalents thereof.

What is claimed is:

1. A method comprising:
applying an electric charge to a conductive substrate immersed in a bath that includes coating particles, wherein the electric charge is configured to uniformly distribute the coating particles on the conductive substrate; and
altering a deposition of the coating particles on the conductive substrate with a magnetic field.

2. The method of claim 1, wherein altering the deposition of the coating particles comprises coupling a magnet to the conductive substrate, wherein the magnet is configured to generate a pattern on a surface of the conductive substrate with the coating particles.

3. The method of claim 1, wherein altering the deposition of the coating particles comprises altering a thickness of the coating particles on a surface of the conductive substrate.

4. The method of claim 1, wherein applying the electric charge to the conductive substrate comprises applying a positive charge to the conductive substrate.

5. The method of claim 1, wherein applying the electric charge to the conductive substrate comprises applying a negative charge to the conductive substrate.

6. The method of claim 1, further comprising:
immersing the conductive substrate in the bath that includes the coating particles, wherein the coating particles comprise transparent coating particles,

7. The method of claim 1, further comprising:
curing the altered deposition of the coating particles.

8. An apparatus, comprising:
a conductive substrate; and
electrically deposited coating particles disposed on the conductive substrate, wherein the deposited coating particles are arranged into a pattern generated by a magnetic field.

9. The apparatus of claim 8 wherein the electrically deposited coating particles comprise transparent coating particles.

10. The apparatus of claim 8, wherein the conductive subs rate is a metallic cover associated with a computing system.

11. The apparatus of claim 8, wherein the electrically deposited coating particles disposed on the conductive substrate have a first thickness on a first portion of the conductive substrate and a second thickness on a second portion of the conductive substrate.

12. The apparatus of claim 11, wherein the first thickness is less than the second thickness and the first thickness is configured to reveal the conductive substrate.

13. The apparatus of claim 8 wherein the pattern correspond to a shape of a magnet used to generate the magnetic field.

14. The apparatus of claim 8, wherein the conductive substrate is a metallic substrate.

15. The apparatus of claim 8, wherein the electrically deposited coating particles comprise a positive charge.
